(19) United States
(12) Patent Application Publication
(10) Pub. No.: US 2025/0189611 A1
(43) Pub. Date: Jun. 12, 2025

(54) Circuit arrangement for evaluating an output signal, and sensor device

(71) Applicant: Balluff GmbH, Neuhausen (DE)

(72) Inventor: Marton Palmann, Neuhausen (DE)

(73) Assignee: Balluff GmbH, Neuhausen (DE)

(21) Appl. No.: 18/965,229

(22) Filed: Dec. 2, 2024

(30) Foreign Application Priority Data
Dec. 6, 2023 (DE) 10 2023 134 122.7

(51) Int. Cl. G01R 35/00; G01R 27/26

(52) U.S. Cl. CPC G01R 35/007; G01R 27/2605; G01R 27/2611

(57) ABSTRACT

A circuit arrangement (10) for evaluating the output signal of an inductive or capacitive proximity switch (105) for switching processes in the low to medium frequency range, comprising a transistor (T) in an emitter circuit, the base of which can be fed an input signal (Vdem), at the collector of which an output signal (Vs) characterising a switching process can be tapped off and the emitter of which is set to a predefined potential (VRef), is characterised in that a coupling capacitor (Ck) is connected between emitter and base which transmits interfering brief voltage peaks at the base directly to the emitter.

The present invention relates to a circuit arrangement for evaluating the output signal of an inductive or capacitive proximity switch for switching processes in the low to medium frequency range, comprising a transistor in an emitter circuit, the base of which is fed an input signal, at the collector of which an output signal characterising a switching process can be tapped off and the emitter of which is set to a predefined potential. The frequency range of relevance here is defined by Standard IEC 609547 May 2. For the present proximity switch, point 9.5.2 of this Standard is particularly relevant.

The invention furthermore relates to a sensor device having an inductive or capacitive proximity switch and an evaluation circuit which comprises an oscillator, a demodulator for outputting the demodulated signal and a comparator for comparing the demodulated signal with a reference signal and for outputting an output signal depending on the comparison, wherein the comparator is realised by an abovementioned circuit arrangement.

### PRIOR ART

Proximity switches or proximity sensors are used in a huge variety of industrial fields. For example, inductive proximity switches are used to detect the presence of a ferrous metal or a steel. Such inductive proximity switches use an internal oscillating circuit, which is also referred to hereinafter as an oscillator, to generate a high-frequency magnetic field at their end face. In this case, a metallic element arranged in the region of the end face is lightly magnetised, whereby energy from the high-frequency magnetic field is absorbed and the oscillator voltage is thus reduced. A comparator connected downstream detects this and actuates for example an output switching amplifier in the case of a set switching distance or oscillation level. As a result, a switching process takes place when the metallic object approaches the inductive proximity switch. Such proximity switches are used in this way for the contactless detection of approaching objects.

Similarly, capacitive proximity switches can also be used for such purposes.

The switching distances can be set by dimensioning the oscillator and the evaluation unit accordingly.

Used in particular as evaluation circuit arrangement of the output signal of an inductive or capacitive proximity switch for switching processes in the low to medium frequency range are bipolar transistors in the emitter circuit, the base of which can be fed an input signal, at the collector of which an output signal characterising a switching process can be tapped and the emitter of which is set to a predefined potential. A switching process takes place whenever the input signal reaches a corresponding voltage in comparison to the predefined potential, taking the base-emitter voltage into account. Such circuit arrangements for evaluating the output signal of inductive or capacitive proximity switches are in other words comparators for comparing the input signal, which corresponds to the demodulated signal of such a sensor device, and the reference signal, which corresponds to the predefined potential at the emitter of the transistor.

A problem in this case is electromagnetic interference, which in particular can have an influence on the oscillator. Such sensor devices having proximity switches can in some cases not meet the requirements of the necessary standards relating to EMC (electromagnetic compatibility). Problems arise, for example, in the case of ESD (electrostatic discharge). Such electrostatic discharges can, for example, interrupt the oscillations in the oscillator, thereby triggering a switching process even though no object to be detected is approaching the proximity switch.

The invention is based on the object of improving a circuit arrangement and a sensor device described in the introduction to the effect that electromagnetic interference exerts no influence on the switching signal, in particular that electrostatic discharges do not trigger any unwanted switching processes and that the overall EMC is improved.

### DISCLOSURE OF THE INVENTION

The object is solved by a circuit arrangement for evaluating the output signal of an inductive or capacitive proximity switch for switching processes in the low to medium frequency range comprising a transistor in an emitter-circuit, the base of which can be fed an input signal, at the collector of which an output signal characterising a switching process can be tapped off and the emitter of which is set to a predefined potential, in that a coupling capacitor is switched between emitter and base which transmits interfering brief voltage peaks at the base directly to the emitter.

In other words, brief voltage peaks that could lead to an undesired switching process are masked by this coupling capacitor, in that the emitter potential is raised to some extent in the same way as the input signal at the base of the transistor. Common-mode interference is not influenced by this circuit configuration.

According to one aspect of the invention, the emitter is set to the predefined potential by a voltage divider.

The low to medium frequency range of the switching processes is preferably between 50 Hz and 1.5 KHz, in particular between 100 Hz and 1 KHz.

The sensor device according to the invention with an inductive or capacitive proximity switch and an evaluation circuit, which comprises an oscillator, a demodulator for outputting a demodulated signal, and a comparator for comparing the demodulated signal with a reference signal and for outputting an output signal depending on the comparison, is characterised in that the comparator is realised by an above-described circuit arrangement, wherein the demodulated signal corresponds to the input signal at the base of the transistor and the reference signal corresponds to the predefined potential at the emitter of the transistors, and wherein the coupling capacitor couples high-frequency interference from the demodulated signal to the reference signal.

Such high-frequency interference is, for example, voltage peaks caused by an electrostatic discharge. Coupling the high-frequency interference from the modulated signal to the reference signal prevents, for the abovementioned reasons, undesired switching processes from signalling that a metallic object for example is approaching the proximity switch.

### BRIEF DESCRIPTION OF THE DRAWINGS

Exemplary embodiments of the invention are shown in the drawings and explained in more detail in the following description.

FIG. 1 shows a schematic illustration of a sensor device known from the prior art.

FIG. 2 shows a schematic illustration of a sensor device according to the invention.

FIG. 3 shows a circuit arrangement known from the prior art for evaluating the output signal of an inductive or capacitive proximity switch.

FIG. 4 shows a circuit arrangement according to the invention for evaluating the output signal of an inductive or capacitive proximity switch.

### EMBODIMENTS OF THE INVENTION

A sensor device known from the prior art for an inductive or capacitive proximity switch 105 has an evaluation circuit 100 which comprises an oscillator 110, a demodulator 120 for outputting a demodulated signal Vdem and a comparator 130 for comparing the demodulated signal Vdem with a reference signal VRef and for outputting an output signal Vs depending on the comparison.

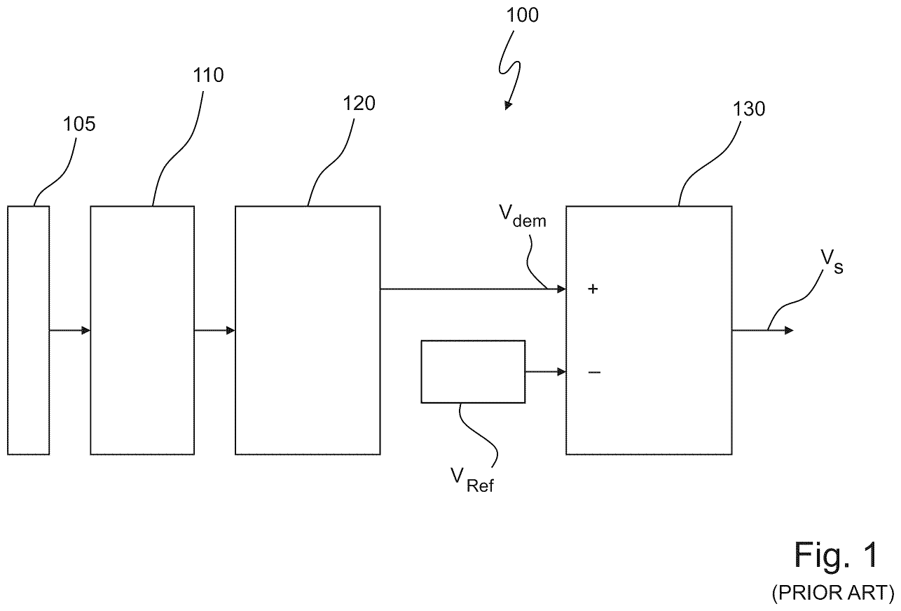

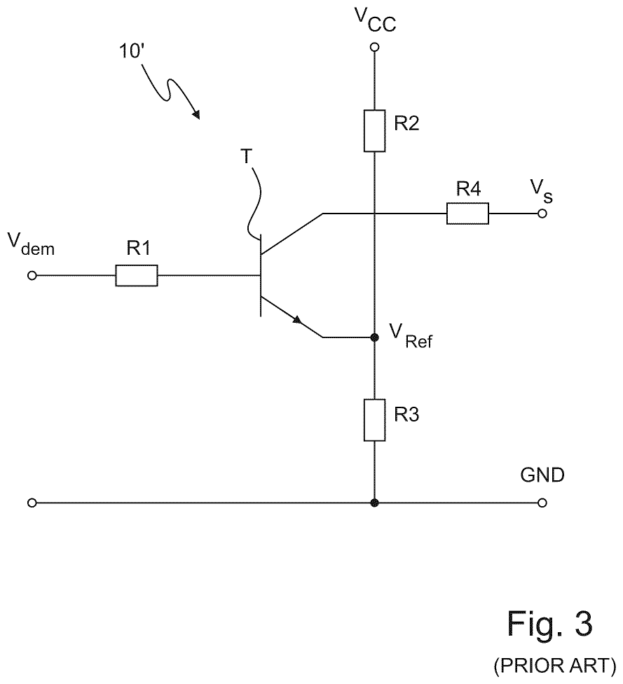

The comparator 130 is realised by a circuit arrangement, shown in FIG. 3 and known from the prior art, for evaluating the output signal of the proximity switch, i.e. the demodulated signal Vdem. This circuit arrangement comprises a bipolar transistor T in an emitter-circuit, the emitter of which is set by a voltage divider R2, R3 to a predefined potential with respect to the supply voltage Vcc, in the present case the reference signal or the reference voltage VRef. The input signal can be fed to the base of the transistor T via a resistor R1, this input signal in the circuit arrangement according to FIG. 1 corresponding to the demodulated signal output by the demodulator 120 the demodulated voltage Vdem. The output signal or the output voltage Vs is present at a resistor R4 connected downstream of the collector, which output signal or voltage is supplied for example to a further (not shown) amplifier stage and evaluated. A switching process takes place whenever the demodulated signal Vdem corresponds to the reference signal VRef plus the base-emitter voltage of the transistor T. A desired switching distance can be set by appropriately configuring the circuit of the transistor T and the other switching elements shown in FIG. 1.

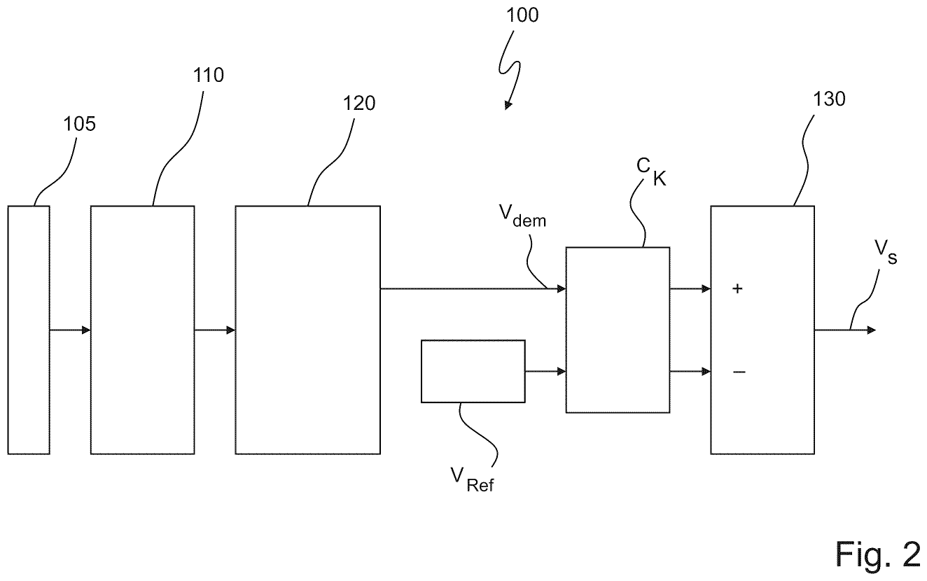

If high-frequency interference is present at the sensor device and thus at the switching device, this can lead to the demodulated signal Vdem being increased briefly even though no metallic object is approaching the (inductive) proximity switch 105. In this case, a switching process takes place and the output signal Vs erroneously signals the approach and the presence of a metallic object in the detection range of the proximity switch 105. Such high-frequency interference can be caused, for example, by electrostatic discharge or by other electromagnetic influences. In order to overcome this, a sensor device according to the invention, which is shown in FIG. 2 and in which the same elements are provided with the same reference signs as in FIG. 1, has a coupling capacitor CK which couples high-frequency interference from the demodulated signal Vdem to the reference signal VRef. If, for example, the demodulated signal Vdem is now raised because of such a high-frequency interference, the reference signal VRef is raised at the same time and in the same way by the coupling capacitor CK and a switching process is prevented thereby. This effectively prevents any high-frequency interference. Common-mode interference does not have an influence on the circuit, by contrast. The coupling capacitor CK therefore “couples” the input signal, the demodulated signal Vdem, to the reference signal VRef.

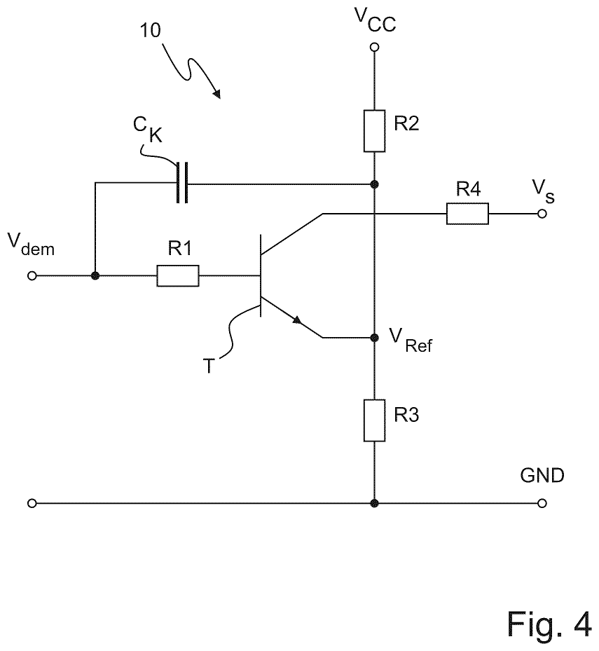

The coupling capacitor CK is switched between the emitter potential, which corresponds to the reference signal VRef, and the input signal, which corresponds to the demodulated signal Vdem, as is shown in the circuit arrangement according to the invention for evaluating the output signal, shown in FIG. 4, in which the same reference signs are used as in FIG. 3. In this way, the abovementioned high-frequency interference, present at the base of the transistor T is transmitted directly to the emitter of the transistor T, whereby the emitter potential and thus the reference signal VRef is “raised” in the case of high-frequency interference in the same way as the input signal present at the base, in other words the demodulated signal Vdem.

The advantage of this simple circuit configuration is that complicated modifications to the demodulator, for example a change to the limit frequency of the demodulator realised as a low-pass filter or a new dimensioning of the oscillator and of the sensor element can be avoided. This would lead to a complicated circuit design, increased effort and higher development costs or manufacturing costs. In contrast, owing to the easy-to-realise coupling capacitor CK, an inexpensive and effective solution can be realised which avoids the EMC of such sensor devices and in particular the insensitivity to electrostatic discharge (GSD).

1. Circuit arrangement for evaluating the output signal of an inductive or capacitive proximity switch for switching processes in the low to medium frequency range, comprising a transistor in an emitter circuit, the base of which can be fed an input signal (Vdem), at the collector of which an output signal (Vs) characterising a switching process can be tapped off and the emitter of which is set to a predefined potential (VRef), characterised in that a coupling capacitor (Ck) is connected between emitter and base which transmits interfering brief voltage peaks at the base directly to the emitter.

2. Circuit arrangement according claim 1, characterized in that the emitter is set to the predefined potential by a voltage divider.

3. Circuit arrangement according to claim 1, characterized in that the low to medium frequency range is between 50 Hz and 1.5 KHz, in particular between 100 Hz and 1 KHz.

4. Sensor device having an inductive or capacitive proximity switch and an evaluation circuit, which comprises an oscillator, a demodulator for outputting a demodulated signal (Vdem), and a comparator for comparing the demodulated signal (Vdem) with a reference signal (VRef) and for outputting an output t signal (Vs) depending on the comparison, characterized in that the comparator is realized by a circuit arrangement according to claim 1, wherein the demodulated signal (Vdem) corresponds to the input signal at the base of the transistor and the reference signal (VRef) corresponds to the predefined potential to the emitter of the transistor, and wherein the coupling capacitor couples high-frequency interference from the demodulated signal (Vdem) to the reference signal (VRef).
